(19) United States
(12) Patent Application Publication
(10) Pub. No.: US 2009/0072357 A1
(43) Pub. Date: Mar. 19, 2009

(54) Integrated shielding process for precision high density module packaging

(76) Inventors: Jinbang Tang, Chandler, AZ (US); Darrel R. Frear, Phoenix, AZ (US); Jong-Kai Lin, Chandler, AZ (US)

Correspondence Address: HAMILTON & TERRILE, LLP - FREESCALE, P.O. BOX 203518, AUSTIN, TX, 78720, US

(21) Appl. No.: 11/854,776

(22) Filed: Sep. 13, 2007

(51) Int. Cl. H01L 23/552; H01L 21/56

(52) U.S. Cl. 257/659; 438/114; 257/E21.502; 257/E23.114

(57) ABSTRACT

An electromagnetic interference (EMI) and/or electromagnetic radiation shield is formed on a plurality of encapsulated modules by attaching a plurality of modules (30-33) to a process carrier (10) using a double side adhesive tape (12) before encapsulating the modules with a molding compound (16), and then forming shielding via ring structures (51-54) in the molding compound (16) to surround and shield each module. After removing the adhesive tape (12) to expose a surface of the encapsulated modules, a multi-layer circuit substrate (101) is formed over the exposed surface, where the circuit substrate includes shielding via structures (121-124) that are aligned with and electrically connected to the shielding via ring structures (51-54), thereby encircling and shielding the circuit module(s).

### BACKGROUND OF THE INVENTION

1. Field of the Invention

The present invention is directed in general to the field of semiconductor devices. In one aspect, the present invention relates to semiconductor packaging devices which are shielded to protect against electromagnetic interference (EMI).

2. Description of the Related Art

Semiconductor devices need to be protected from electromagnetic interference (EMI) which is the undesired electrical signals, or noise, in electronic system circuitry caused by the unintentional coupling of electromagnetic field energy from other circuitry, such as wires, printed circuit board conductors, connector elements, connector pins, cables, and the like. For example, multiple chip modules (MCM) are semiconductor devices having a plurality of discrete microelectronic devices (e.g., a processor unit, memory unit, related logic units, resistors, capacitors, inductors, and the like) that are connected together on a single MCM substrate. Conventional approaches for shielding against EMI have used board or system level EMI shielding techniques, though this does not provide protection against interference caused by modules within the board or system. Other shielding techniques have attempted to protect against radio/electromagnetic interference by using conformal shielding technologies to packaging the individual circuit modules (e.g., MCMs), such as by using wire bond grounding connection techniques, laser-drilled via grounding connection techniques, or double-cutting methods. An example of this approach is with mobile phone designs which seek to push EMI shielding from metal lids on phone boards to the discrete packaged RF module level. However, these techniques require extra substrate space to apply the shielding, or impose an extra space and double saw operation, or otherwise increase the cost and complexity of the packaging process. In addition, these techniques typically require post mold assembly processes to add conformal EMI shielding to the packaged circuit modules, such as by drilling blind vias in the package molding compound which are then filled with a conductive material to form a shielding via in the molding compound. However, there are a number of alignment problems with forming blind vias that can impact device reliability and yield, such as creating electrical shorts to signal pads and/or signal paths or connection failures from mis-alignment.

Accordingly, there exists a need for a packaging scheme that provides improved EMI shielding at the module level. There is also a need for an improved process for forming and aligning shielding via structures in packaged circuit modules. In addition, there is a need for a reliable and cost effective semiconductor device package that provides reliable EMI shielding with little or no impact on the size of the packaging device. There is also a need for improved packaging processes and devices to overcome the problems in the art, such as outlined above. Further limitations and disadvantages of conventional processes and technologies will become apparent to one of skill in the art after reviewing the remainder of the present application with reference to the drawings and detailed description which follow.

### BRIEF DESCRIPTION OF THE DRAWINGS

The present invention may be understood, and its numerous objects, features and advantages obtained, when the following detailed description is considered in conjunction with the following drawings, in which:

FIG. 1 is a cross-sectional view of a plurality of chip modules (and grounding frame) which are mounted on a layer of double-sided tape or attachment chemical and a process carrier substrate and a encapsulated with a molding compound in accordance with one embodiment;

FIG. 2 illustrates a perspective view of the encapsulated plurality of chip modules (panel) depicted in FIG. 1;

FIG. 3 illustrates processing subsequent to FIG. 1 with a cross-sectional view of the encapsulated plurality of chip modules after vias are formed in the molding compound between individual circuit modules by drilling through at least the molding compound;

FIG. 4a illustrates an example perspective view of the encapsulated plurality of chip modules (panel) depicted in FIG. 3 to show how the vias may be formed as continuous grooves or openings;

FIG. 4b illustrates an example plan view of an encapsulated plurality of chip modules (panel) depicted in FIG. 3 to show how the vias may be formed as a plurality of discrete openings of any desired shape;

FIG. 5 illustrates processing subsequent to FIG. 3 with a cross-sectional view of the encapsulated plurality of chip modules after a conductive shielding layer is formed in at least the molding compound vias;

FIG. 6 illustrates processing subsequent to FIG. 5 with a cross-sectional view of the encapsulated plurality of chip modules after the molding compound is thinned;

FIG. 7 illustrates processing subsequent to FIG. 6 with a cross-sectional view of the encapsulated plurality of chip modules after a shielding cover layer is formed over the thinned molding compound;

FIG. 8a illustrates processing subsequent to FIG. 7 with a cross-sectional view of the encapsulated plurality of chip modules after the double-sided tape and process carrier is removed;

FIG. 8b illustrates a cross sectional view of an alternative embodiment of an encapsulated plurality of chip modules after the double-sided tape and process carrier is removed, where the encapsulated plurality of chip module are formed with a grounding frame in place before the shielding via structures are formed in the molding compound;

FIG. 9 illustrates processing subsequent to FIG. 8a with a cross-sectional view of the encapsulated plurality of chip modules after micro vias are formed on the backside of the encapsulated plurality of chip modules and in alignment with the shielding via structures;

FIG. 10 illustrates processing subsequent to FIG. 9 with a cross-sectional view of the encapsulated plurality of chip modules after micro pads are formed in alignment with the micro vias formed on the backside of the encapsulated plurality of chip modules;

FIG. 11 illustrates processing subsequent to FIG. 10 with a cross-sectional view of the encapsulated plurality of chip modules after a multilayer substrate is formed with shielding via structures which are electrically connected to the shielding via structures formed in the molding compound;

FIG. 12 illustrates processing subsequent to FIG. 11 with a cross-sectional view of the encapsulated plurality of chip modules after individual chip modules are singulated; and

FIG. 13 illustrates a sample fabrication sequence flow for fabricating chip modules with a conformal EMI shielding.

It will be appreciated that for simplicity and clarity of illustration, elements illustrated in the drawings have not necessarily been drawn to scale. For example, the dimensions of some of the elements are exaggerated relative to other elements for purposes of promoting and improving clarity and understanding. Further, where considered appropriate, reference numerals have been repeated among the drawings to represent corresponding or analogous elements.

### DETAILED DESCRIPTION

A method and apparatus are described for fabricating high density encapsulated semiconductor device or devices with integrated shielding. As a preliminary step, a plurality of circuit devices and an optional embedded grounding frame are assembled as a panel by mounting the circuit devices on a process carrier using a removable attachment device, such as a thick double-sided tape or chemical attachment layer. This assembly occurs prior to forming the underlying circuit substrate. Once the circuit devices are affixed to the removable attachment device, the circuit devices are encapsulated with a molding compound or resin. By drilling the molding compound to form via openings between individual circuit devices (e.g., with a laser cutting tool or other appropriate cutting technique) and then filling the via openings with a conductive or other appropriate shielding material (e.g., by sputtering, spraying, plating, etc.), shielding via ring structures are formed in the molding compound to encircle and shield the circuit device(s). In various embodiments, the via openings formed in the molding compound can be formed with at least a single continuous opening or groove that encircles one (or more) individual circuit devices, thereby forming one or more shielding via ring structures to shield the one (or more) individual circuit devices from electromagnetic interference. Alternatively, the via openings can be formed as a plurality of discrete openings of any desired shape (e.g., circular, square, oval, rectangular, etc.) that are positioned to encircle one (or more) individual circuit devices, thereby forming one or more shielding via ring structures to shield the one (or more) individual circuit devices from electromagnetic interference. At this point or subsequently, a layer of a conductive material or other appropriate shielding material is formed on the top of the molding compound as a top shielding cover which makes electrical contact with the shielding via ring structures formed in the molding compound. As formed, the shielding via ring structures extend completely through the molding compound and are exposed on the bottom of the molding compound (device I/O side). After the removable attachment device is released, a multi-layer circuit substrate with shielding via structures is then built on the bottom of the molding compound. By building up the circuit substrate with its shielding via structures properly aligned and electrically connected to the exposed shielding via ring structures formed in the bottom of the molding compound, an integrated EMI shield is provided for specific functional circuit block and/or entire module. In selected embodiments, the shielding via ring structure(s) may be connected with a ground ring. After forming the multi-layer circuit substrate with shielding via structures electrically connected to the shielding via ring structures, the panel is cut, sawed, or otherwise separate into singulated dice.

Various illustrative embodiments will now be described in detail with reference to the accompanying figures. While various details are set forth in the following description, it will be appreciated that the present invention may be practiced without these specific details, and that numerous implementation-specific decisions may be made to the invention described herein to achieve the device designer's specific goals, such as compliance with process technology or design-related constraints, which will vary from one implementation to another. While such a development effort might be complex and time-consuming, it would nevertheless be a routine undertaking for those of ordinary skill in the art having the benefit of this disclosure. For example, selected aspects are depicted with reference to simplified cross sectional drawings of a semiconductor device without including every device feature or geometry in order to avoid limiting or obscuring the present invention. It is also noted that, throughout this detailed description, certain materials will be formed and removed to fabricate the semiconductor structure. Where the specific procedures for forming or removing such materials are not detailed below, conventional techniques to one skilled in the art for growing, depositing, removing or otherwise forming such layers at appropriate thicknesses shall be intended. Such details are well known and not considered necessary to teach one skilled in the art of how to make or use the present invention.

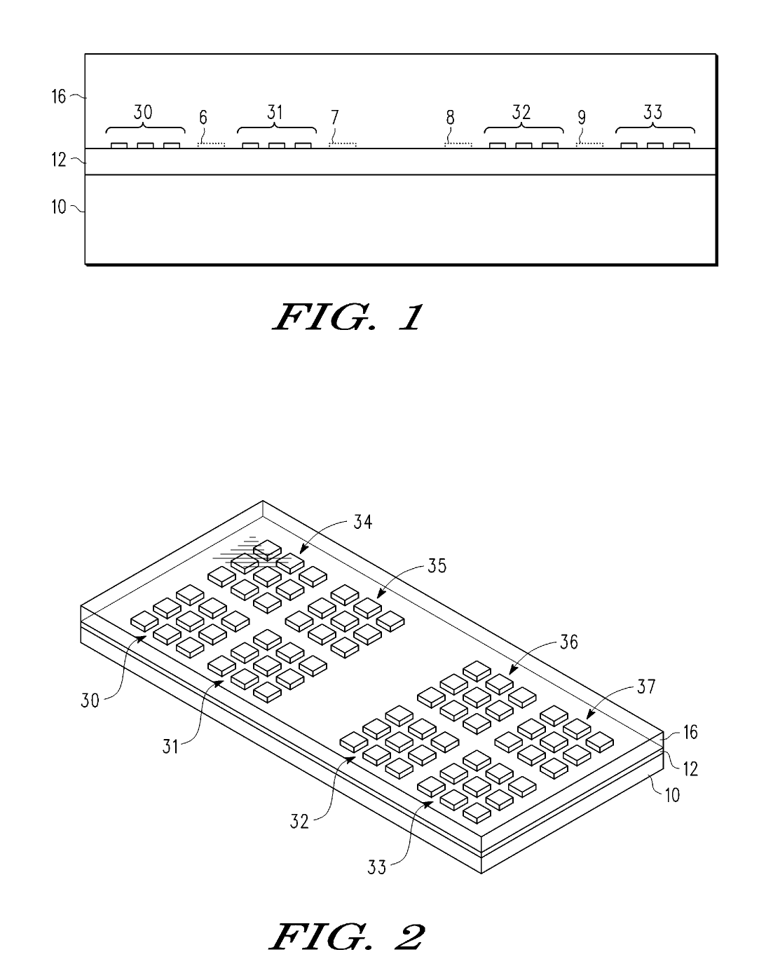

Turning now to FIG. 1, a cross-sectional view is illustrated of a plurality of chip modules 30-33 which are mounted as a panel on a removable attachment device 12 (e.g., a double-sided tape or an attachment chemical layer) and a process carrier substrate 10. In addition, FIG. 2 is provided to illustrate a perspective exterior view of the encapsulated plurality of chip modules (panel) depicted in FIG. 1. As illustrated, each chip module (e.g., 30) includes a plurality of microelectronic devices (e.g., a processor unit, memory unit, related logic units, resistors, capacitors, inductors, and the like), though it will be appreciated that the advantages of the present invention may also be obtained if each chip module includes only a single microelectronic or circuit device. If desired, each chip module may also have a grounding frame disposed adjacent to the chip module circuit(s) from grounding frame layers 6-9. In FIG. 1 (but not in FIG. 2), the grounding frame elements 6-9 are depicted with dashed lines to indicate that these structures are optionally provided at this point in the fabrication process. For example, grounding frame layers 6 and 7 form a grounding frame or ring around a first circuit device 31, while grounding frame layers 8 and 9 form a grounding frame or ring around a second circuit device 32. Each microelectronic device in the chip modules 30-33 (and any grounding frame layers) may be mounted or attached on top of the removable attachment device 12 and process carrier 10 to fix them in place. The purpose of the removable attachment device 12 is to secure the encapsulated chip modules 30-33 during the subsequent fabrication process so that a shielding material may be integrally formed in the encapsulation packaging prior forming the underlying multilayer circuit substrate. With this purpose in mind, any desired attachment technique may be used to implement the removable attachment device 12, including but not limited to applying a thick double-sided tape, glue layer or other removable die attach material between the lower surface of the circuit substrate and the process carrier 10.

As further illustrated in FIGS. 1 and 2, the plurality of chip modules 30-37 are encapsulated with an insulating package body or molding 16 which may be formed by applying, injecting or otherwise forming an encapsulant to seal and protect the microelectronic devices in the chip modules from moisture, contamination, corrosion, and mechanical shock. For example, after affixing the microelectronic devices 30-37 to the removable attachment device 12, an encapsulation process is performed to cover the chip modules with a mold compound or mold encapsulant. The mold encapsulant may be a silica-filled resin, a ceramic, a halide-free material, or some other protective encapsulant layer. The mold encapsulant is typically applied using a liquid, which is then heated to form a solid by curing in a UV or ambient atmosphere. The encapsulant can also be a solid that is heated to form a liquid and then cooled to form a solid mold. As will be appreciated, any desired encapsulant process may be used. At this point, the removable attachment device 12 and process carrier 10 may be removed if desired; however, the removal step can also occur later in the fabrication process, such as described hereinbelow where the removable attachment device 12 is released after the shielding via structures are formed in the insulating package body 16.

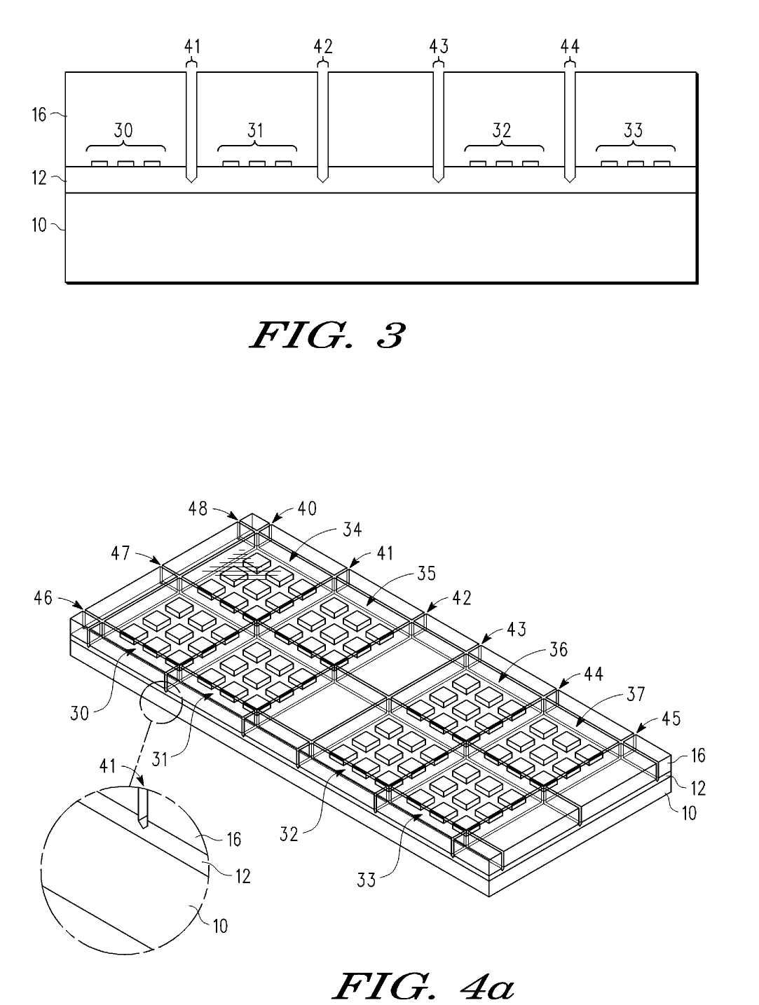

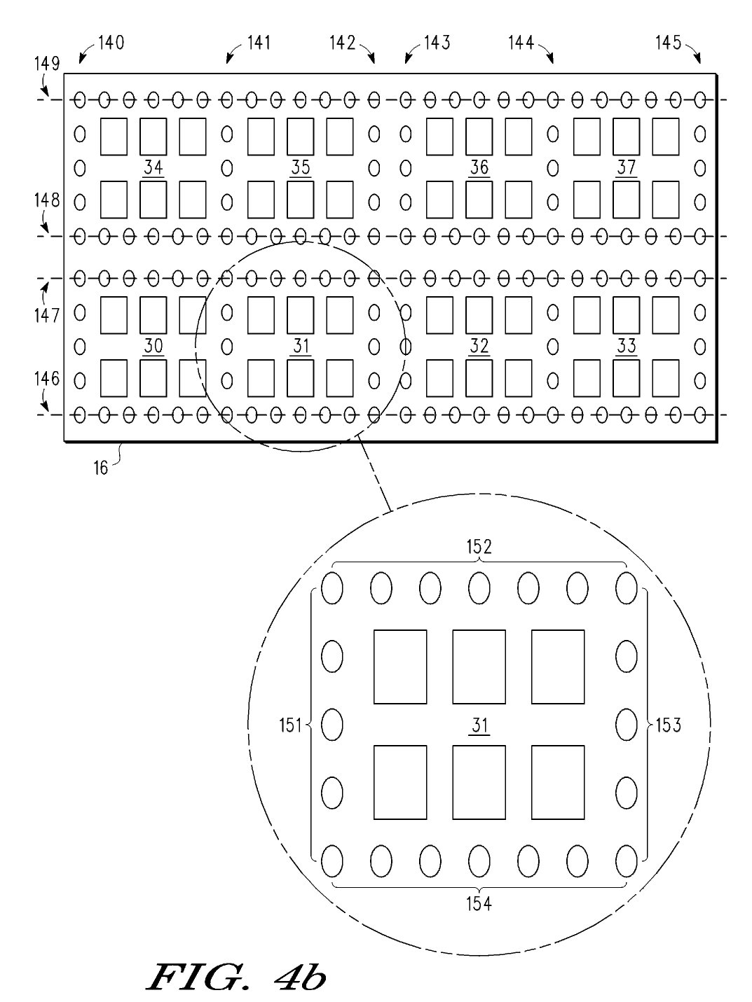

After the packaged panel assembly is formed, the insulating package body 16 is cut to form via openings 41-44 between individual chip modules 30-33. This is depicted in FIG. 3 which illustrates processing subsequent to FIG. 1 with a cross-sectional view of the encapsulated plurality of chip modules 30-33 after via openings 41-44 are formed in the insulating package body 16 by cutting down through at least the insulating package body 16. In addition, FIG. 4a is provided to illustrate an example perspective exterior view of the encapsulated plurality of chip modules (panel) depicted in FIG. 3. As depicted, the cuts through the insulating package body 16 and into the removable attachment device 12 form grooves 40-48 which separate the chip modules 30-37, though it will be appreciated that the via openings can be made with shallower cuts. As illustrated in FIG. 4a, the via openings 40-48 may be formed in the insulating package body 16 with continuous cuts or grooves that intersect with one another, thereby forming one or more via openings that are positioned to encircle one (or more) individual chip modules. However, instead of using continuous groove openings, the via openings can be formed as a plurality of discrete openings that are positioned to collectively encircle one (or more) individual chip modules. An example implementation is depicted in FIG. 4b, which illustrates an example plan view of an encapsulated plurality of chip modules 31-37 to show how each of the via openings 140-149 may be formed in the insulating package body 16 as a plurality of discrete openings of any desired shape (e.g., circular, square, oval, rectangular, etc.). Thus, a plurality of separate via openings are drilled to surround the circuit module(s) 31, including via openings 151, 152, 153 and 154. By positioning a plurality of discrete openings to encircle one (or more) individual chip modules, shielding via ring structures can subsequently be formed by filling to shield the one (or more) individual circuit modules from electromagnetic interference. Though not shown in FIG. 4a or 4b, more than one ring of via openings can be formed around each circuit module(s) or device(s), thereby enhancing the shielding benefit provided by the subsequently formed shielding via structures.

As seen from the foregoing, the via openings can be formed as either continuous or discrete openings having any desired shape, provided that the via openings encircle the chip module(s) or device(s) that are to be shielded. In addition, the placement of the via openings (and the subsequently formed shielding via ring structures) may be controlled to provide local shielding for individual modules, as well as global shielding from external EMI sources. As an example of local shielding, the shielding via ring structures formed in the openings 151-154 shield module 31 from module 30, as well as from module 32. As an example of global shielding, the shielding via ring structures formed in the openings 147-146 help shield the modules 30-33 from external modules (e.g., modules 34-35). Those skilled in the art will appreciate that the shape, size and spacing of separate via openings may be controlled so as to achieve the EMI shielding benefits of the present invention, even when a single continuous groove opening is not used, because separate shielding via structures will effectively acts as a single shielding structure when positioned sufficiently close to one another. For this reason, the remaining description is provided with reference to the groove embodiment depicted in FIGS. 3 and 4a, even though selected embodiments may be implemented with separate and discrete via openings, such as shown in FIG. 4b.

The via openings 41-44 are shown in FIG. 3 as having substantially vertical sidewalls that are separated by a predetermined minimum distance so that a conductive or shielding layer may be subsequently deposited to fill the via openings during subsequent processing. However, it will be appreciated that the via openings 41-44 may instead have angled sidewalls which may facilitate the subsequent deposition of the conductive/shielding layer, though at the expense of consuming valuable real estate. For example, the via openings 41-44 may be formed with a cutting instrument that forms a V-shaped cut for the entire via opening (not shown) since this shape is easier to cover with the deposited conductive shielding layer. With such a cut, the via opening is wider at the top of the mold compound and narrower at the bottom where it terminates in the removable attachment device 12. Whichever shape is used, the cut may be made with a saw having a cutting blade, a laser, or any other instrument that can controllably form the via openings 41-44 into the insulating package body and between the individual chip modules 30-37. In selected embodiments, the cutting instrument provides a depth cut that is greater than the height of the insulating package body 16 so that the groove extends into the removable attachment device 12, as illustrated with the enlarged cross-section shown in FIG. 4. In this way, the shielding layer subsequently formed in the via openings and connected to the shielding via structures in the subsequently-formed multi-layer circuit substrate will completely encapsulate the singulated modules. In addition, by controlling the cutting action so that the via openings terminate in the removable attachment device 12, the position of the individual chip modules 31-37 in relation to the process carrier 10 is maintained by virtue of the adhesive function provided by the removable attachment device 12, which helps facilitate subsequent handling or processing of the individual chip modules. Of course, it will be appreciated that any desired technique may be used to form the via openings 41-44, including but not limited to chemical patterning techniques, such as selectively etching the openings by patterning and anisotropically etching the via openings 41-44.

When cutting all the way down to the attachment device 12, it is important to position and align the cut lines so that the cuts do not intersect with the microelectronic devices in the chip modules 30-37. This is illustrated in FIG. 3, where each via opening (e.g., groove 41) is positioned between the chip modules (e.g., modules 30 and 31). One benefit of forming the via openings in the insulating package body 16 before forming the multi-layer circuit substrate is that the cutting of the via openings can not intersect with any conductive signal or voltage paths in the multi-layer circuit substrate since it is not yet formed. As will be appreciated, intersections with such conductive paths should ordinarily be avoided to prevent a short between the conductive path and the conductive shield layer subsequently formed in the via openings. However, in selected embodiments, the positioning and alignment of the via openings 41-44 may be deliberately controlled to intersect with the embedded grounding frame layers 6-9 (shown in FIG. 1) formed at the bottom of the in the insulating package body 16. This positioning allows a direct electrical connection to be established between the embedded grounding frame layers 6-9 and their respective conductive/shielding material subsequently formed in the via openings 41-44.

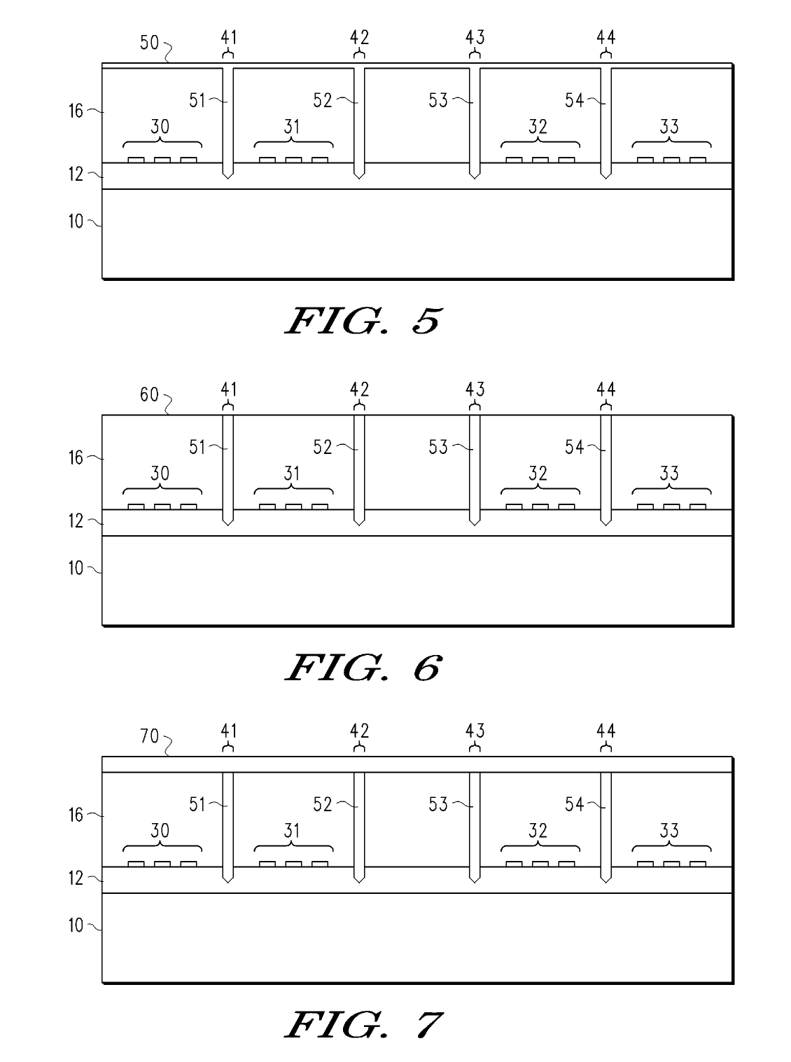

FIG. 5 illustrates processing subsequent to FIG. 3 with a cross-sectional view of the encapsulated plurality of chip modules 30-33 after a conductive shielding layer 50 is formed over the insulating package body 16 and in the via openings 41-44, thereby forming shielding via structures 51-54. The conductive shielding layer 50 can be a polymer, metal, metal alloy (such as a ferromagnetic or ferroelectric material), ink, paint, the like or combinations of the above. In one embodiment, the conductive shielding layer 50 is formed from aluminum (Al), copper (Cu), nickel iron (NiFe), tin (Sn), zinc (Zn), or the like, including any combination of one or more of the foregoing. For example, by forming the conductive shielding layer 50 as a combination of a non-ferromagnetic material and ferromagnetic material (e.g., a layer of copper and a layer of NiFe), then the circuit modules are protected from electromagnetic fields that are both electric and magnetic with a electromagnetic or broadband shield. Prior to depositing the conductive shielding layer 50, the upper surface of the insulating package body 16 and the via openings 41-44 may be prepared so that the conductive shielding layer 50 will adhere. The conductive shielding layer 50 can be deposited by physical vapor deposition (PVD), chemical vapor deposition (CVD), atomic layer deposition (ALD), electrolytic plating, electro-less plating, flame spray, conductive paint spray, vacuum metallization, pad printing, sputtering, evaporation, dispensing, spray coating, or the like, including any combination of one or more of the foregoing. While the conductive shielding layer 50 may be formed on each groove sidewall to a predetermined thickness, in selected embodiments the conductive shielding layer 50 is formed to partially or completely fill the via openings 41-44, depending on the desired shielding effectiveness. As will be appreciated, if the via openings 41-44 are only partially filled, subsequent processing will be used to completely encapsulate the individual chip modules with conductive shielding material, as described hereinbelow.

FIG. 6 illustrates processing subsequent to FIG. 5 with a cross-sectional view of the encapsulated plurality of chip modules 30-33 after the insulating package body 16 and shielding via structures 51-54 are optionally thinned. By grinding, sawing, abrading, polishing or using any desired technique to remove part of the insulating package body 16 and shielding via structures 51-54, the overall profile thickness of the final packaging may be reduced, thereby reducing the size of the final packaged devices. However, if the insulating package body 16 is thinned, any conductive shielding layer 50 formed on its top surface will be removed, and must be replaced with a subsequent process step in order to provide the device shielding. While this replacement process can occur at any time before the final package is assembled and singulated, in selected embodiments, a conductive shielding replacement layer may be added after the insulating package body 16 is thinned. For example, FIG. 7 illustrates processing subsequent to FIG. 6 with a cross-sectional view of the encapsulated plurality of chip modules 31-33 after a shielding cover layer 70 is formed over the thinned insulating package body 16 and in electrical contact with the shielding via structures 51-54. The shielding cover layer 70 can be deposited by PVD, CVD, ALD, electrolytic plating, electro-less plating, flame spray, conductive paint spray, vacuum metallization, pad printing, sputtering, evaporation, dispensing, spray coating, or the like, including any combination of one or more of the foregoing.

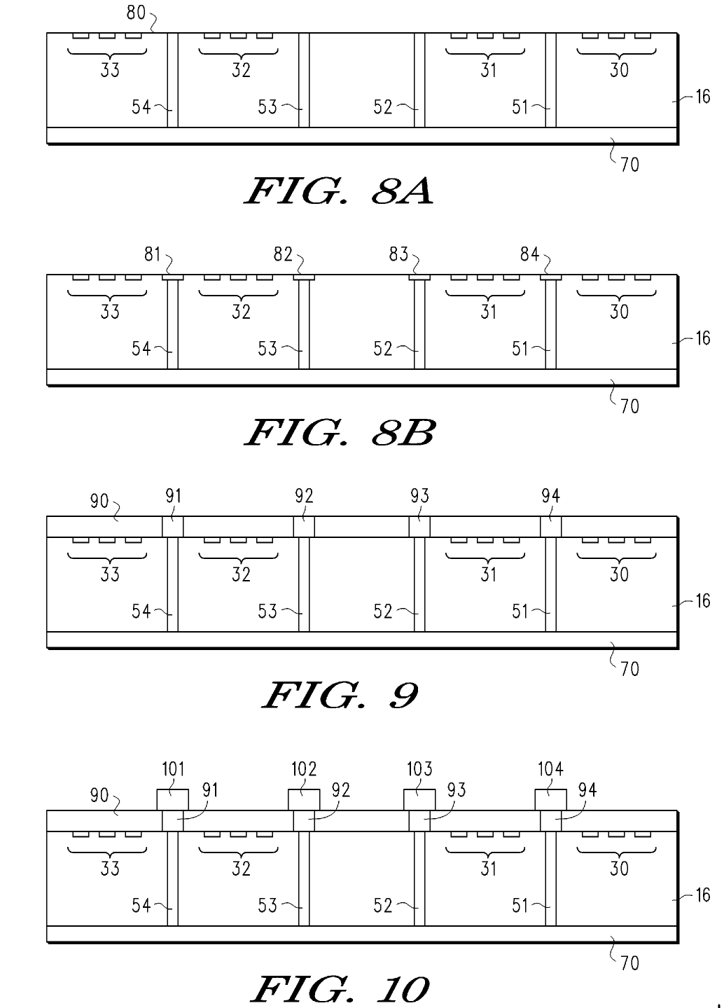

After forming the conductive/shielding layer to fill the via openings 41-44 and cover the insulating package body 16, the encapsulated modules are separated or released from the removable attachment device 12 and process carrier 10. This is illustrated in FIG. 8a depicts the processing subsequent to FIG. 7 with a cross-sectional view of the encapsulated plurality of chip modules 30-33 after the removable attachment device 12 and process carrier 10 are removed. As depicted in FIG. 8a, the panel of encapsulated modules is turned upside down so that the shielding cover layer 70 is now on the bottom, and the shielding via structures 51-54 and plurality of chip modules 30-33 are exposed on the top of the insulating package body 16. In this position, a multi-layer circuit substrate structure may be built up over the panel of encapsulated modules, where the circuit substrate structure includes shielding via structures that are formed with conductive and/or shielding material to completely surround the individual circuit module(s). For example, the multi-layer circuit substrate structure may be fabricated one layer at a time to include a circuit substrate shielding via structures formed of a conductive/shielding material. By properly positioning the circuit substrate via structures so that they are electrically connected to the exposed shielding via structures 51-54 formed in the insulating package body 16, individual circuit module(s) may be enclosed and shielded by the shielding via structures. As a result, each individual encapsulated module 30-33 has one or more shielding via ring structures formed in the insulating package body 16 to encircle and shield the circuit module, and also has one or more circuit substrate via structures formed in the multi-layer circuit substrate that also encircle and shield the circuit module. As described herein, a “via structure” or “via ring structure” refers to a single “through via” and to any combination of conductive paths (e.g., grounding pad structures, embedded grounding frames, micro pads, traces, etc.) that together form a shielding structure.

As indicated above, the encapsulated plurality of chips may be constructed to include embedded grounding frame layers 6-9 formed in the insulating package body 16 (shown with dashed lines in FIG. 1) to facilitate the formation of circuit substrate shielding vias in alignment with the shielding via structures 51-54. An example is shown in FIG. 8b which illustrates a cross sectional view of an alternative embodiment of an encapsulated plurality of chip modules 30-33 where the encapsulated plurality of chip modules 30-33 are formed with a grounding frame layers 6-9 in place before the shielding via structures 51-54 are formed in the insulating package body 16. In this case, any cutting process used to form the via openings 41-44 will be controlled to stop before cutting through the grounding frame layers 6-9. FIG. 8b shows that, after the double-sided tape 12 and process carrier 10 are removed, the embedded grounding frame layers 6-9 present a larger connection surface on which the subsequently-formed circuit substrate shielding vias can be formed with enhanced precision. Another benefit of including embedded grounding frame layers 6-9 with a larger connection surface is that the shielding via structures formed around individual modules can be constructed as multi-via ring structures for enhanced shielding. For example, a plurality of concentric shielding via ring structures in the insulating package boy 16 may be formed around each module to provide additional shielding against electromagnetic interference.

While any desired fabrication sequence may be used to form the multi-layer circuit substrate, an example sequence is illustrated beginning with FIG. 9 which illustrates processing subsequent to FIG. 8a with a cross-sectional view of the encapsulated plurality of chip modules 30-33 after micro vias 91-94 are formed on the backside of the encapsulated plurality of chip modules and in alignment with the shielding via structures 51-54. The individual micro vias may be fabricated by forming an insulating layer 90 with openings over at least the shielding via structures 51-54, and then depositing, sputtering or otherwise forming a conductive and/or shielding material in the openings to form the micro vias 91-94. The insulating layer 90 may be formed by applying a patterned adhesive layer of insulating material, by depositing a layer that is then selectively etched, or using any desired technique. Alternatively, the micro vias 91-94 may be formed by applying a patterned adhesive layer of conductive/shielding material, by depositing a conductive/shielding layer that is then selectively etched, or using any desired technique. Though not shown, it will be appreciated that the insulating layer 90 may also have openings over the individual circuit module(s) to permit electrical connection to any signal lines or supply voltage lines in the circuit module(s). In this way, each microelectronic device in the chip module may be mounted or attached to the circuit substrate using surface mount techniques, including, but not limited to wire bond, tape-automated bond, solder ball connectors, flip-chip bonding, etc. For example, each microelectronic device may have die bond pads (not shown) which are electrically connected to landing pads (not shown) on the circuit substrate, such as by using wire bonds.

Additional layers of the multi-layer circuit substrate may then formed over the first insulating layer 90 and micro vias 91-94 to construct the circuit substrate shielding vias. For example, FIG. 10 illustrates processing subsequent to FIG. 9 with a cross-sectional view of the encapsulated plurality of chip modules 30-33 after micro pads 101-104 are formed in alignment with the micro vias 91-94 formed on the backside of the encapsulated plurality of chip modules. The individual micro pads 101-104 may be fabricated by forming an insulating layer (not shown) with openings over at least the micro vias 91-94 and then depositing, sputtering or otherwise forming a conductive and/or shielding material in the openings to form the micro pads 101-104; by applying a patterned adhesive layer of conductive/shielding material; by depositing a conductive/shielding layer that is then selectively etched; or using any desired technique.

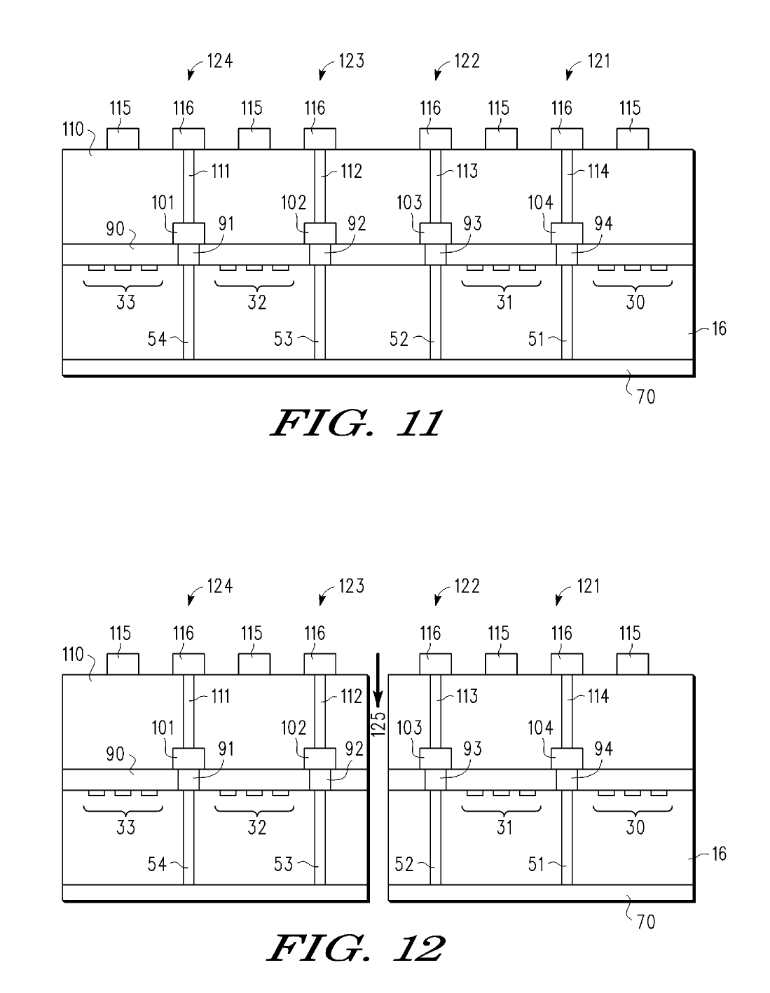

As the multi-layer circuit substrate continues to be built up, circuit substrate shielding via structures 121-124 are formed in substantial alignment with the shielding via structures 51-54. An example process is shown in FIG. 11 which illustrates processing subsequent to FIG. 10 with a cross-sectional view of the encapsulated plurality of chip modules 30-33 after a multilayer substrate 110 is formed with via structures 111-114 that are formed in alignment with the micro pads 101-104. Again, the via structures 111-114 may be fabricated from one or more conductive/shielding layers that are formed over at least the micro pads 101-104 using any desired technique. However formed, the via structures 121-124 are electrically connected to the shielding via structures 51-54 formed in the insulating package body 16. The circuit substrate 110 also includes conductive paths (not shown) to electrically couple signals and/or voltages to and from the chip module. Thus, the circuit substrate 110 may be formed to any desired shape and thickness, and may include any desired features for use in forming a functional semiconductor package. In addition, the circuit substrate 110 may be fabricated with any desired material, such as a relatively thin, flexible film of an electrically insulative material (such as an organic polymer resin), or a rigid, substantially planar member fabricated from any known, suitable materials, including, but not limited to, insulator-coated silicon, a glass, a ceramic, an epoxy resin, bismaleimide-triazine (BT) resin, or any other material known in the art to be suitable for use as a circuit substrate.

The finally completed panel may have formed on the circuit substrate one or more I/O pads. As shown in simplified schematic form in FIG. 11, supply voltage and signal I/O pads 115 may be formed so that they can be electrically connected through the multi-layer circuit substrate to the respective chip modules 30-33. In addition, reference voltage pads 116 may be formed so that they can be electrically connected to the via structures 111-114 in the multi-layer circuit substrate, and in turn to the shielding via ring structures 51-54 and shielding cover layer 70.

At this point when the multi-layer circuit is constructed, a conductive/shielding coating may be applied to any exposed surface of the insulating package body 16, such as by depositing a metal film, conductive polymer, etc. For example, the conductive shielding replacement layer described above with reference to FIG. 7 may instead be formed after the multi-layer circuit substrate is formed.

Once the multi-layer circuit substrate panel is completed, the panel is cut, sawed, or otherwise separate into singulated dice. FIG. 12 illustrates processing subsequent to FIG. 11 with a cross-sectional view of the encapsulated plurality of chip modules 30-33 after individual chip modules are singulated by sawing through predetermined cut paths, thereby forming chip modules in which shielding via structures are formed to shield individual circuit devices. As depicted in FIG. 12, a cut line 125 that is positioned between a first shielding via structure 53, 92, 102, 112 and a second shielding via structure 52, 93, 103, 113 separates the panel into a first chip module (including circuit devices 30 and 31) and a second chip module (including circuit devices 32 and 33), where each circuit device is individually shielded by the shielding via structures formed in the circuit substrate and insulating package body 16. By positioning the cut line 125 between the shielding structures, the chip module(s) 32 is shielded by the shielding via ring structures 53, 54 and the shielding via structures 111, 112. Likewise, the chip module(s) 31 is shielded by the shielding via ring structures 51, 52 and the shielding via structures 113, 114. Though FIG. 12 shows only a single shielding structure 54, 101 next to the chip module(s) 33, it will be appreciated that additional shielding structures (not shown) may be formed to encircle and shield the module(s) 33.

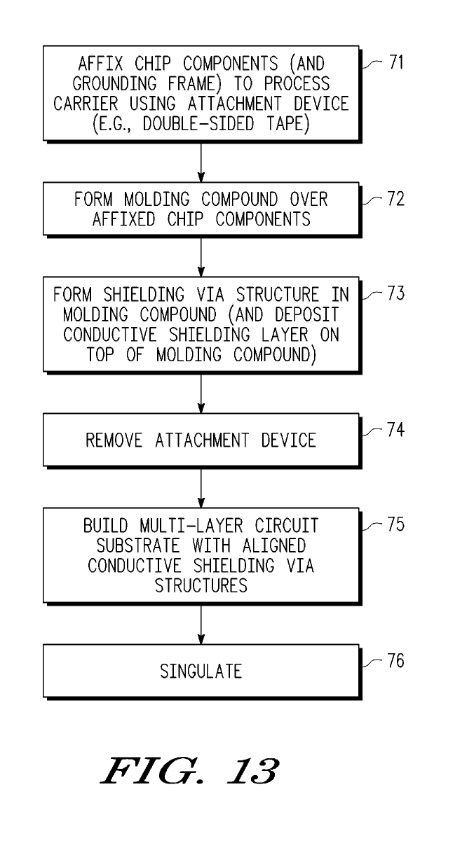

Turning now to FIG. 13, there is illustrated a sample fabrication sequence flow for fabricating chip modules with a conformal EMI shielding. As an initial step 71, a plurality of chip modules/components are mounted or affixed on the surface of a process carrier using a releasable attachment device, such as a double sided tape layer or glue layer. With the chip modules/components assembled on the attachment device, a molding compound is formed to encapsulate the chip modules/components (step 72). Shielding via structures are then formed in the molding compound by cutting down through at least the molding compound to form via openings, and then filling the via openings with a conductive or shielding material, such as by depositing a conductive material over the molding compound and into the via openings (step 73) using any desired technique, such as plating, sputtering, spraying, etc. If the molding compound is thinned at this point, a replacement layer of conductive or shielding material must subsequently be formed on the top of the molding compound. Once the shielding via structures are formed in the molding compound, the removable attachment device is released (step 74), and a multi-layer circuit substrate is then built on the encapsulated chip modules/components (74). The multi-layer circuit substrate is formed to include conductive shielding via structures that are aligned with and electrically coupled to the shielding via structures formed in the molding compound, so that individual circuit devices or components are surrounded and shielded by the shielding via structures. Finally, the individual chip modules are cleaned and separated from one another (step 76).

In one form, there is provided herein a method for making a package assembly with conformal EMI shielding. As disclosed, a plurality of microelectronic devices (such as circuit devices, grounding frames, etc.) are attached to a releasable attachment device (such as a double-sided tape or glue layer) and encapsulated by forming a molding compound or resin over the microelectronic devices to form an encapsulation package having a first surface that contacts the releasable attachment device and a second surface opposite the first surface. Via openings are formed in the encapsulation package to surround an encapsulated microelectronic circuit, such as by cutting through the second surface of the encapsulation package by performing a saw or laser cut. The via openings are then at least partially filled with a conductive layer to form a shielding via ring structure surrounding the encapsulated microelectronic circuit. After removing the removable attachment device from the first surface of the encapsulation package, the encapsulated microelectronic circuit is exposed at the first surface of the encapsulation package, and a circuit substrate is then formed on that surface. The circuit substrate may be formed as a multi-layer circuit substrate having shielding via structure which is substantially aligned with and electrically connected to the shielding via ring structure formed in the encapsulation package. In various embodiments, the shielding via structure formed in the circuit substrate is formed from one or more conductive layers, such as a micro via layer, a micro pad layer, a grounding pad, an embedded grounding frame, a trace layer that are electrically connected to the shielding via ring structure.

In another form, there is provided a high density RF module package having an encapsulant package formed to encapsulate one or more microelectronic circuits so as to expose the one or more microelectronic circuits at a bottom surface of the encapsulant package. In the encapsulant package, one or more shielding via ring structures are formed to shield each of the microelectronic circuits against electromagnetic interference. In various embodiments, the shielding via ring structures are formed with conductive (e.g., metal or polymer) material that completely covers a top surface of the encapsulant package and at least partially fills one or more via openings drilled into the encapsulant package before the circuit substrate is formed. As formed, the encapsulant package may also include an embedded ground frame which is exposed at the bottom surface of the encapsulant package and positioned in alignment with a shielding via ring structure. The package also includes a circuit substrate which is formed on the bottom surface of the encapsulant package after forming the first shielding via ring structure. The circuit substrate may be formed as a multi-layer circuit substrate having a shielding via structure which is substantially aligned with and electrically connected to the shielding via ring structure formed in the encapsulant package. The shielding via structure may be formed with one or more conductive layers in the circuit substrate, such as a micro via layer, a micro pad layer, a grounding pad, an embedded grounding frame, or a trace layer that is electrically connected to the shielding via ring structure.

In yet another form, there is provided a method of forming a semiconductor package wherein a package panel is provided that includes a plurality of circuit devices that are releasably attached to a process carrier and encapsulated with an encapsulation package so as to expose the one or more circuit devices at a bottom surface of the encapsulation package. In an example embodiment, the package panel is provided by providing a process carrier that is releasably attached to a plurality of circuit devices (and optionally, a ground frame) with a double-sided tape layer or glue layer, and then encapsulating the plurality of circuit devices (and ground frame) with a mold encapsulant to form an encapsulation package. One or more shielding via ring structures may be formed in the encapsulation package to surround a first encapsulated circuit device by drilling through a top surface of the encapsulation package (e.g., with a laser cut) to form via openings surrounding the first encapsulated circuit device, and then forming a conductive layer over the encapsulation package and in the via openings. After removing the process carrier from the bottom surface of the encapsulation package, the first encapsulated circuit device is exposed at the first surface of the encapsulation package. On this exposed bottom surface, a circuit substrate is formed, such as by forming a multi-layer circuit substrate having shielding via structure which is substantially aligned with and electrically connected to the shielding via ring structure formed in the encapsulation package. In various embodiments, the shielding via structure is formed with one or more conductive layers formed in the multi-layer circuit substrate, such as a micro via layer, a micro pad layer, a grounding pad, an embedded grounding frame, or a trace layer that is electrically connected to the shielding via ring structure. Subsequently, the first encapsulated circuit device and its shielding via ring structure may be singulated, such as by sawing or cutting.

Although the described exemplary embodiments disclosed herein are directed to various packaging assemblies and methods for making same, the present invention is not necessarily limited to the example embodiments which illustrate inventive aspects of the present invention that are applicable to a wide variety of packaging processes and/or devices. Thus, the particular embodiments disclosed above are illustrative only and should not be taken as limitations upon the present invention, as the invention may be modified and practiced in different but equivalent manners apparent to those skilled in the art having the benefit of the teachings herein. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A method for making a package assembly with EMI shielding, comprising:
attaching a plurality of microelectronic devices to a releasable attachment device;
encapsulating the plurality of microelectronic devices by forming an encapsulation package over the plurality of microelectronic devices, the encapsulation package comprising a first surface that contacts the releasable attachment device and a second surface opposite the first surface;
forming one or more via openings through the second surface of the encapsulation package to surround a first encapsulated microelectronic circuit;
forming a conductive layer over the encapsulation package to at least partially fill the one or more via openings, thereby forming a shielding via ring structure surrounding the first encapsulated microelectronic circuit;
removing the removable attachment device from the first surface of the encapsulation package to thereby expose the first encapsulated microelectronic circuit at the first surface of the encapsulation package; and
forming a circuit substrate on the first surface of the encapsulation package.

2. The method of claim 1, where attaching the plurality of microelectronic devices to a releasable attachment device comprises applying a double-sided tape layer to attach the plurality of microelectronic devices to a process carrier.

3. The method of claim 1, where attaching the plurality of microelectronic devices to a releasable attachment device comprises applying a glue layer to attach the plurality of microelectronic devices to a process carrier.

4. The method of claim 1, where attaching the plurality of microelectronic devices to a releasable attachment device comprises attaching a grounding frame to the releasable attachment device.

5. The method of claim 1, where forming one or more via openings comprises cutting through the second surface of the encapsulation package to form one or more via openings by performing a laser cut through the encapsulation package.

6. The method of claim 1, where forming a conductive layer comprises depositing a conductive layer by physical vapor deposition, chemical vapor deposition, atomic layer deposition, electrolytic plating, electroless plating, flame spray, conductive paint spray, vacuum metallization, pad printing, sputtering, evaporation, dispensing or spray coating.

7. The method of claim 1, where forming a circuit substrate on the first surface of the encapsulation package comprises forming a multi-layer circuit substrate having a shielding via structure which is substantially aligned with and electrically connected to the shielding via ring structure formed in the encapsulation package.

8. The method of claim 7, where the shielding via structure comprises a conductive layer, such as a micro via layer, a micro pad layer, a grounding pad, an embedded grounding frame, a trace layer that are electrically connected to the shielding via ring structure.

9. A high density RF module package comprising:
an encapsulant package formed to encapsulate one or more microelectronic circuits so as to expose the one or more microelectronic circuits at a bottom surface of the encapsulant package;
at least a first shielding via ring structure formed in the encapsulant package to shield each of the one or more microelectronic circuits against electromagnetic interference; and
a circuit substrate formed on the bottom surface of the encapsulant package after forming the first shielding via ring structure.

10. The high density RF module package of claim 9, where the circuit substrate comprises a multi-layer circuit substrate in which a shielding via structure is substantially aligned with and electrically connected to the first shielding via ring structure formed in the encapsulant package.

11. The high density RF module package of claim 9, where first shielding via ring structure comprises a conductive material that is formed to at least partially fill one or more via openings drilled into the encapsulant package before the circuit substrate is formed.

12. The high density RF module package of claim 9, where the encapsulant package comprises an embedded ground frame which is exposed at the bottom surface of the encapsulant package and positioned in alignment with the at least first shielding via ring structure.

13. The high density RF module package of claim 9, where the circuit substrate comprises a shielding via structure formed with one or more conductive layers in the circuit substrate, such as a micro via layer, a micro pad layer, a grounding pad, an embedded grounding frame, or a trace layer that is electrically connected to the first shielding via ring structure.

14. The high density RF module package of claim 9, where the first shielding via ring structure comprises a conductive metal or polymer material that completely covers a top surface of the encapsulant package and fills one or more via openings drilled into the encapsulant package before the circuit substrate is formed.

15. A method of forming a semiconductor package comprising:
providing a package panel comprising a plurality of circuit devices that are releasably attached to a process carrier and encapsulated with an encapsulation package so as to expose the one or more circuit devices at a bottom surface of the encapsulation package;
drilling through a top surface of the encapsulation package to form via openings surrounding a first encapsulated circuit device;
forming a conductive layer over the encapsulation package and in the via openings, thereby forming a shielding via ring structure surrounding the first encapsulated circuit device;
removing the process carrier from the bottom surface of the encapsulation package to thereby expose the first encapsulated circuit device at the first surface of the encapsulation package;
forming a circuit substrate on the bottom surface of the encapsulation package; and
singulating the first encapsulated circuit device and its shielding via ring structure.

16. The method of claim 15, where providing a package panel comprises:
providing a process carrier;
releasably attaching a plurality of circuit devices to the process carrier with a double-sided tape layer or glue layer; and
encapsulating the plurality of circuit devices with a mold encapsulant to form an encapsulation package.

17. The method of claim 15, further comprising releasably attaching a ground frame to the process carrier using a releasable attachment device so that the ground frame is exposed at a bottom surface of the encapsulation package and positioned in alignment with the shielding via ring structure.

18. The method of claim 15, where drilling through the top surface of the encapsulation package comprises performing a laser cut through the encapsulation package.

19. The method of claim 15, where forming a circuit substrate comprises forming a multi-layer circuit substrate having shielding via structure which is substantially aligned with and electrically connected to the shielding via ring structure formed in the encapsulation package.

20. The method of claim 19, where forming a multi-layer circuit substrate comprises forming a shielding via structure with one or more conductive layers in the multi-layer circuit substrate, such as a micro via layer, a micro pad layer, a grounding pad, an embedded grounding frame, or a trace layer that is electrically connected to the shielding via ring structure.
